(19) United States
(12) Patent Application Publication
(10) Pub. No.: US 2026/0165177 A1
(43) Pub. Date: Jun. 11, 2026

(54) CONFIGURABLE ELECTRICAL PAD DIE PACKAGE

(71) Applicant: Rambus Inc., San Jose, CA (US)

(72) Inventors: Thomas Vogelsang, Jericho, VT (US); Robert E. Palmer, Chapel Hill, NC (US); Evan Lawrence Erickson, Chapel Hill, NC (US)

(21) Appl. No.: 19/408,239

(22) Filed: Dec. 3, 2025

Related U.S. Application Data
(60) Provisional application No. 63/728,405, filed on Dec. 5, 2024.

(51) Int. Cl. H10W 72/20; H10B 12/00; H10W 20/43; H10W 72/90

(52) U.S. Cl. CPC H10W 72/244; H10B 12/00; H10W 20/43; H10W 72/248; H10W 72/9445

(57) ABSTRACT

The embodiments herein are directed to technologies for electrical pad orientation within dual data rate packages. One semiconductor package includes interconnect layers, a substrate layer, and a ball gate array (BGA), the interconnect layers between the substrate layer and the BGA. Electrical connections between electrical pads in the substrate layer and electrical pads in the interconnect layers are configured to remain separate and create electrical connection equity between the electrical pads and the corresponding solder balls of the BGA.

### RELATED APPLICATIONS

This application claims the benefit of priority from U.S. Provisional Patent Application No. 63/728,405 , filed Dec. 5, 2024, the entire contents of which are hereby incorporated by reference herein.

### BACKGROUND

Computing system memory generally includes one or more dynamic random access memory (DRAM) integrated circuits, referred to herein as DRAM devices, which are connected to one or more processors. There are different types of memory modules, for example, Double Data Rate Types one through five (DDR1-DDR5). Advancements in DDR technology have lowered power consumption, increased prefetching performance, enhanced error correction, and enabled larger capacity support. As each successive DDR technology has been released, structure and use requirements for the DDR modules are adjusted.

In particular, DDR5 modules have improved performance over earlier modules by utilizing a dual-channel architecture. The dual-channel architecture allows for double prefetch capabilities by utilizing half of the DRAM die on a module for a first channel processing and the other half of the DRAM die for a second channel processing. Future iterations of DDR technologies may implement dual-channel architecture on a single package. However, existing ball grid array (BGA) structures utilized by the dual-channel architecture of future DDR may create an inconsistency in wire length between electrical pads and solder balls of the BGA. Variation in wire length may impact efficiency, speed, delay, power consumption, production costs, and other performance metrices of the DDR. Thus, there is a need to enable more configurable DDR architecture to utilize the increased capabilities of the DDR dual-channel configuration, pin location cost savings, and limit degradation of performance because of wire length variation.

### BRIEF DESCRIPTION OF THE DRAWINGS

The present disclosure is illustrated by way of example, and not by way of limitation, in the figures of the accompanying drawings.

FIG. 1 is a block diagram illustrating a top view of a configuration of a dual-channel double data rate (DDR) package including a ball grid array (BGA) and electrical pads within a circuit stripe for connecting integrated circuits to the BGA in accordance with some embodiments of the present disclosure.

FIG. 2A is a block diagram illustrating a top view of a vertical pad interconnect dual channel DDR package including the electrical pads within the circuit stripe of FIG. 1 and corresponding interconnect electrical pads connected to the electrical pads in accordance with some embodiments of the present disclosure.

FIG. 2B is a block diagram illustrating a top view of the vertical pad interconnect dual channel DDR package of FIG. 2A, and the BGA of FIG. 1, in accordance with some embodiments of the present disclosure.

FIG. 2C is a block diagram illustrating a side view of the vertical pad interconnect dual channel DDR package comprising the substrate layer including the electrical pads, the interconnect layer including the corresponding interconnect electrical pads, the BGA, and the BGA connectors in accordance with some embodiments of the present disclosure.

FIG. 3A is a block diagram illustrating a top view of a vertical edge pad interconnect dual channel DDR package with the electrical pads of FIG. 1 within the circuit stripe and corresponding interconnect electrical pads deposited along multiple sides of the vertical edge pad interconnect dual channel DDR package according to electrical pad type and connected to the electrical pads in accordance with some embodiments of the present disclosure.

FIG. 3B is a block diagram illustrating a top view of the vertical edge pad interconnect dual channel DDR package of FIG. 3A and the BGA of FIG. 1, in accordance with some embodiments of the present disclosure.

FIG. 4A is a block diagram illustrating a top view of the vertical pad interconnect dual channel DDR package of FIG. 2A including the interconnect electrical pads, edge electrical pads deposited on a side of the DDR package and connected to the interconnect electrical pads, and external electrical pads in accordance with some embodiments of the present disclosure.

FIG. 4B is a block diagram illustrating a top view of the vertical edge pad interconnect dual channel DDR package of FIG. 4A and the BGA of FIG. 1, in accordance with some embodiments of the present disclosure.

### DETAILED DESCRIPTION

Many electronic devices (e.g., cell phones, tablets, set-top boxes, etc.) use integrated circuits that have an integrated circuit die in a semiconductor package. As described above, advancements in technology have led to adjustments in semiconductor packages. As such, there is an increased need to allow for adjustability to integrate the semiconductor package into electronic devices to utilize the technological advancements. Specifically, the utilization of dual-channel semiconductor module and package architecture has led to increased processing capacity with each channel, including the ability to prefetch data individually and simultaneously. In the present disclosure, structures are constructed which intentionally adjust the location of semiconductor package components to position the components to access the dual channels more effectively, while allowing the structures to be configurable to certain electronic devices. Specifically, the present disclosure allows for the movement of the electrical pads to prevent a need for crossing wires within the semiconductor device to more logically arrange connections to the ball grid array (BGA) and utilize the space within the electronic device.

Additionally, within electronic devices, space is a high value, finite resource. Allowing adjustment of semiconductor package architecture to fit into electronic devices rather than adjusting electronic devices to fit the semiconductor package can increase usability of the semiconductor package. For example, a module may be better utilized by accessing electronic pads of a certain type at a same area of the semiconductor package. Allowing orientation of the electronic pads within the package to align with that location within the module may cause for more cost efficient wiring. For example, a tall die orientation may fit into electronic devices that are oriented to have additional space in a first direction and have specific electronic requirements fulfilled by a tall die orientation. A wide die orientation may fit into electronic devices that have additional space in a second direction and have specific electronic requirements fulfilled by a wide die orientation.

Traditional DDR architectures can include multiple electrical pads, for example, command array (CA) pads and data queue (DQ) pads, deposited within a circuit stripe of a semiconductor die. The circuit stripe can separate two halves of a BGA. Each half of the BGA can include CA solder balls and DQ solder balls. The dual-channel orientation of the traditional devices can require longer wire lengths from one of the electrical pads to the corresponding solder balls of the BGA than another electrical pad of the same type. For example, a semiconductor package with two DQ pads may traditionally have one DQ pad disposed closer to the DQ designated solder balls and one DQ pad disposed further from the DQ designated solder balls, therefore the wire lengths connecting the second DQ pad to the DQ solder balls would be longer than the wire lengths connecting the first DQ pad to the DQ solder balls.

Aspects of the present disclosure allow a semiconductor package to be oriented and arranged in such a way that wire length within the semiconductor package is distributed more uniformly, and orientation within the module and based on electronic device requirements can be considered. In some embodiments, an interconnect layer can be disposed between the electrical pads and the BGA layer. Within the interconnect layer, one or more interconnect electrical pads can be disposed to be electrically connected to the electrical pads without the electrical connections crossing. For example, three electrical pads may be disposed horizontally within a circuit stripe of the BGA. The interconnect electrical pads may be then disposed perpendicular to the electrical pads, laying horizontally across the circuit stripe of the BGA. Each interconnect electrical pad may be connected via a wire or electrical channel to a corresponding electrical pad. The wires for each connection can be oriented such that no wires cross within the interconnect layer.

In one or more embodiments, the interconnect electrical pads may be disposed within the interconnect layer according to proximity of the BGA solder balls. For example, an interconnect electrical pad of a CA type may be disposed within the interconnect layer proximal to the CA solder balls of the BGA rather than the DQ solder balls of the BGA. In one or more embodiments, the interconnect electrical pads may be disposed within the interconnect layer according to semiconductor die architecture requirements. For example, if an electronic device requires a tall semiconductor die rather than a wide die, the interconnect electrical pads may be disposed within the interconnect layer to orient the semiconductor die tall rather than wide.

In some embodiments, there is a second interconnect layer disposed between the first interconnect layer and the BGA layer. The second interconnect layer can comprise one or more connection lines between the electrical pads and the solder balls of the BGA. In some embodiments, the second interconnect layer can comprise one or more electrical pads to further adjust a location of electrical pads in relation to the BGA within the semiconductor package. In some embodiments, the second interconnect layer is a package substrate and the first interconnect layer is a redistribution layer.

In some embodiments, the substrate layer may include a plurality of memory cells arranged in one or more channels corresponding to electrical pads or the BGA channels. For example, the plurality of memory cells may be arranged in a first channel corresponding to the first DQ pad and a second channel corresponding to the second DQ pad. In some embodiments, the BGA may comprise a first half of the ball grid array, wherein the first half includes a first DQ half of the DQ ball grid array and a first CA half of the CA ball grid array; and a second half of the ball grid array, wherein the second half includes a second DQ half of the DQ ball grid array and a second CA half of the CA ball grid array, wherein the circuit stripe is centered between the first half of the ball grid array and the second half of the ball grid array.

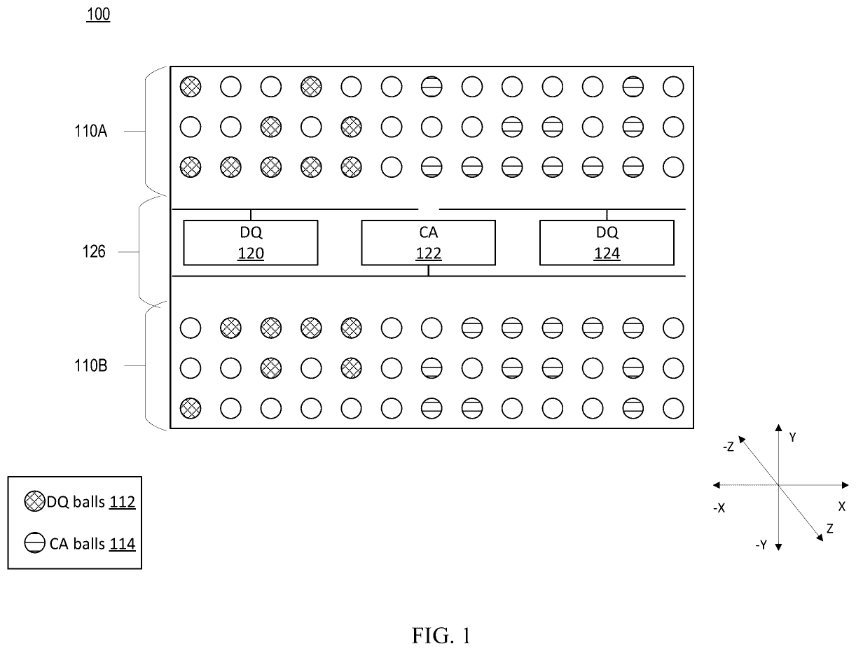

FIG. 1 is a block diagram illustrating a top view of a configuration of a dual-channel double data rate (DDR) package 100 including a ball grid array (BGA) 110 and electrical pads 120, 122, and 124 within a circuit stripe 126 for connecting integrated circuits to the BGA 110 in accordance with some embodiments of the present disclosure. DDR packages are a type of memory technology that allows data to be transferred on both the rising and falling edges of a clock signal. A semiconductor package that supports DDR functionality may include memory cells arranged in a matrix in which memory retrieval will indicate a coordinate from which to retrieve memory. A dual-channel DDR utilizes two separate channels on a single package operating in parallel. In some embodiments, each channel accesses a separate bank of memory cells.

As shown in FIG. 1, the BGA 110 of a dual-channel DDR package 100 can include multiple solder balls arranged into two channels 110A and 110B. As shown, the solder balls can be, in some embodiments, DQ balls 112 and CA balls 114 dedicated to data queue and column array data signals respectively. DQ balls 112 transmit the data signals between the memory cells, via an electrical pad, and a memory controller. The number of DQ balls 112 of a dual-channel DDR package 100 can correspond to the data width of the memory package. For example, a 64-bit package could have 64 DQ balls. CA balls 114 can be used to transmit command and address signals between the memory controller and the memory cells via the electrical pads. Command signals can instruct the memory on what operation to perform (e.g., read, write, etc.), while address signals specify the coordinate location of the memory cell to be accessed.

The dual-channel DDR package 100 is shown to have two channels. The first channel 110A is shown with a number of DQ balls 112 and CA balls 114. Additional balls, such as power balls and ground balls can be interspersed between the DQ balls 112 and the CA balls 114 to electrically connect the dual-channel DDR package 100 to power and ground. Other balls may include, for example, control balls such as reset, alert, and the like to electrically connect the dual-channel DDR package 100 to one or more control sources to receive control signals. The second channel 110B is shown with a number of DQ balls 112 and CA balls 114. The first channel 110A and the second channel 110B can have the same architecture including the same number of DQ balls 112 and CA balls 114, different architecture with the same number of DQ balls 112 and CA balls 114, or different architecture with a different number of DQ balls 112 and CA balls 114. It should be appreciated, that while only two channels are shown, more channels could be included such that additional channels include solder balls of the BGA and memory cells accessible by the electrical pads.

The first channel 110A can be used to complete operations on the memory cells in parallel with operations using the second channel 110B. The operations on the first channel 110A and the second channel 110B can be the same operations being executed simultaneously, or different operations with the first channel 110A and the second channel 110B operating independently.

Communication between the BGA 110 and the memory cells can occur via one or more electrical pads on a substrate layer. Electrical pads can be a type of pad, for example, DQ pads 120 and 124 and CA pad 122, which are configured to enable communication of data signals and command signals respectively. The first DQ pad 120 and the second DQ pad 124 can each indicate a block of DQ pads, such that each DQ pad 120, 124 comprises one or more electrical pads configured for DQ signals. The CA pad 122 can indicate a block of CA pads, such that the CA pad 122 comprises one or more electrical pads configured for CA signals. In dual-channel DDR packages, multiple electrical pads of one type can be connected with the BGA 110. Dual-channel DDR package 100 includes a first DQ pad 120 and a second DQ pad 124 in electrical communication with the DQ balls 112. The first DQ pad 120 of the dual-channel DDR package 100 is the furthermost electrical pad in the circuit stripe 126 in the-X direction. As the DQ balls 112 are in the half of the BGA 110 in the-X direction of all solder balls, the first DQ pad 120 is adjacent to the DQ balls 112. Alternatively, the second DQ pad 124 of the dual-channel DDR package 100 is the furthermost electrical pad within the circuit stripe 126 in the X direction. As the CA balls 114 are in the half of the BGA 110 in the X direction of all solder balls, the second DQ pad 124 is adjacent to the CA balls 114 and separated from the DQ balls 112 by the CA pad 122 within the circuit stripe 126. Based on proximity, electrical connections between the DQ balls 112 and the first DQ pad 120 and the second DQ pad 124 are inequitable. Specifically, the electrical connections (e.g., wire length) from the first DQ pad 120 to the DQ balls 112 are shorter than the electrical connections from the second DQ pad 124 to the DQ balls 112. The difference between the electrical connections can cause less than optimal operation of the dual-channel DDR package as discussed above, therefore there is a need for adjustment of the location of the electrical pads for more equitable electrical connections.

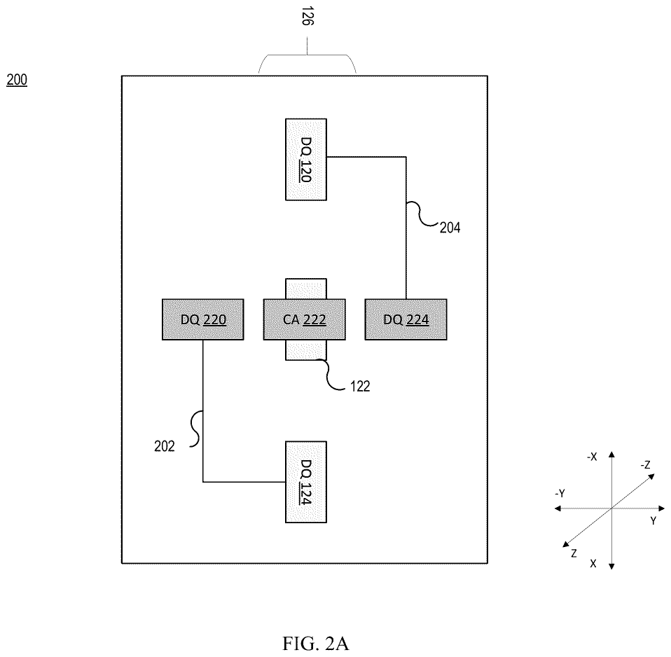

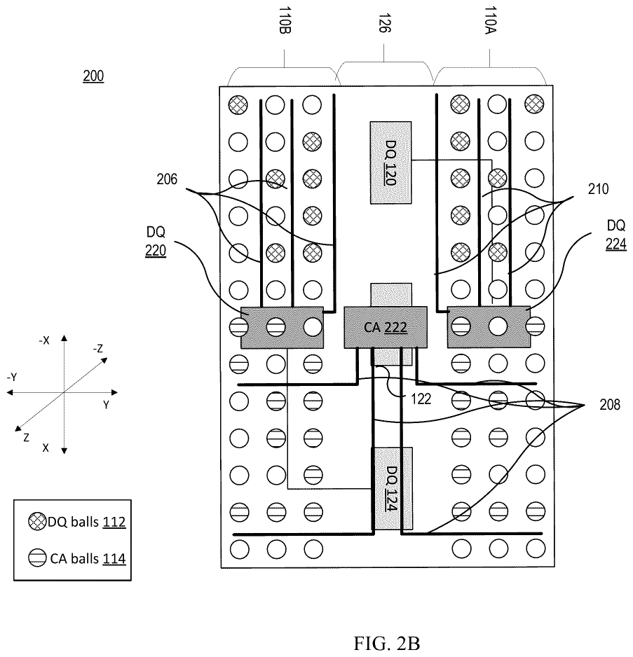

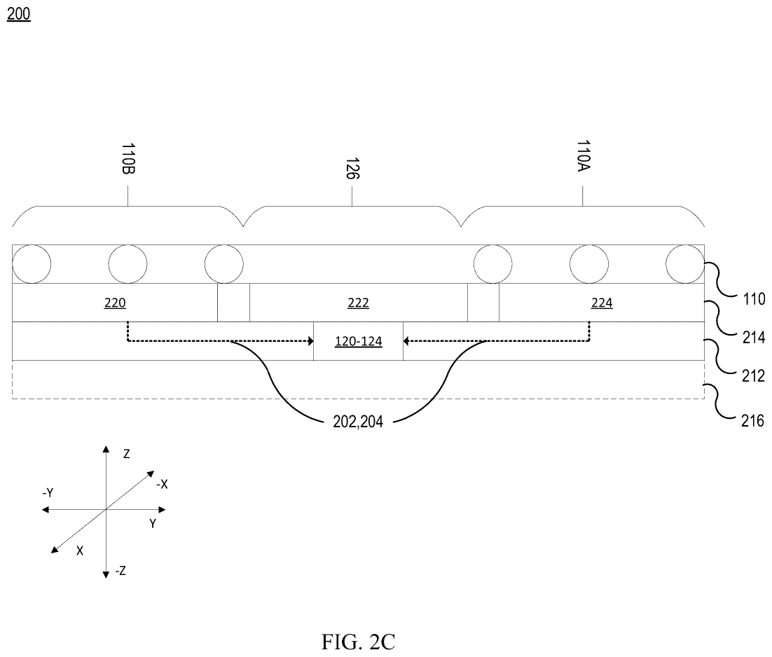

Adjustment of the location of the electrical pads can happen between the BGA 110 and the electric pads 120, 122, and 124. The adjustment (not shown in FIG. 1) can occur on the substrate layer, an interconnect layer, and/or redistribution layer(s) to reposition the electrical pads in relation to the BGA 110. As shown in FIGS. 2A-4B below, interconnect electrical pads can be inserted into intervening layers to execute the adjustment.

FIG. 2A is a block diagram illustrating a top view of a vertical configuration interconnect dual channel DDR package 200 illustrating the electrical pads 120, 122, and 124 within the circuit stripe 126 of FIG. 1 and corresponding interconnect electrical pads 220, 222, and 224 connected to the electrical pads 120, 122, and 124 according to one embodiment. To address the electrical connection concerns above, an interconnect layer can be disposed on a substrate layer in the Z direction. The substrate layer can include the electrical pads 120, 122, and 124, electrical connections, a substrate, and/or one or more electrical components. The interconnect layer can include one or more interconnect electrical pads such as interconnect DQ pad 220, interconnect CA pad 222, and interconnect DQ pad 224. The interconnect DQ pads 220 and 224 can each indicate a block of DQ pads on the interconnect layer, such that each interconnect DQ pad 220, 224 comprises one or more electrical pads configured for DQ signals. The interconnect CA pad 222 can indicate a block of CA pads on the interconnect layer, such that the interconnect CA pad 222 comprises one or more electrical pads configured for CA signals. Further, the interconnect layer can include electrical connections 202 and 204 between the electrical pads 120, 122, and 124 of the substrate layer and the interconnect electrical pads 220, 222, and 224. As shown in FIG. 2A, in one embodiment, the interconnect electrical pads 220, 222, and 224 of the interconnect layer can be oriented orthogonal to the circuit stripe 126 and the electrical pads 120, 122, and 124.

Electrical connections 202 and 204 can be wires, electrical pathways in a substrate, or other methods of electrical transmission. Not shown is an electrical connection between the CA pad 122 of the substrate layer and the interconnect CA pad 222 of the interconnect layer. The electrical connection may be a wire or electrical pathway similar to electrical connections 202 and 204. In some embodiments, the interconnect layer may further include additional electrical components. In some embodiments, the interconnect layer may be configured as a redistribution layer. In some embodiments the redistribution layer may include metal layers, such as copper, disposed on a dielectric substrate to act as the electrical connections. In some embodiments, the redistribution layer may include insulating portions to prevent electrical interference between components. In some embodiments, the electrical pathways may be vias within a substrate of the redistribution layer, such that the vias are small channels of conductive material within the substrate that allow for electrical connection.

FIG. 2B is a block diagram illustrating a top view of the vertical configuration interconnect dual channel DDR package 200 of FIG. 2A and the BGA 110 of FIG. 1 including BGA connectors 206, 208, and 210 according to one embodiment. FIG. 2B illustrates an embodiment in which the BGA 110 is disposed on the interconnect layer in the Z direction. As shown, in an embodiment, electrical pad 120 is situated closer in the X direction to the associated DQ balls 112 of the BGA 110 than electrical pad 124. However, interconnect electrical pads 220 and 224 are equal distance in the X direction from the DQ balls 112 of the BGA 110. As explained above, additional balls of BGA 110, such as power balls and ground balls can be interspersed between the DQ balls 112 and the CA balls 114 to electrically connect the dual-channel DDR package 200 to power and ground. Other balls of BGA 110 may include, for example, control balls such as reset, alert, and the like to electrically connect the dual-channel DDR package 200 to one or more control sources to receive control signals.

Interconnect electrical pad 220, in some embodiments, can be a DQ pad configured to connect with DQ balls 112 of a single channel 110B of the interconnect dual channel DDR package 200 using BGA connectors 206. Interconnect electrical pad 224, in some embodiments, can be a DQ pad configured to connect with DQ balls 112 of a single channel 110A of the interconnect dual channel DDR package 200 using BGA connectors 210. BGA connectors 206 and 210, because of the proximity of interconnect electrical pads 220 and 224 to the DQ balls 112, can be of equal or similar length.

Interconnect electrical pad 222 can, in some embodiments, be oriented relative to the BGA 110 differently than electrical pad 122. For example, interconnect pad 222 can be oriented such that all BGA connectors 208 from the interconnect electrical pad 222 to the CA balls 114 of the BGA 110 connect to the interconnect electrical pad 222 at a same side of the interconnect electrical pad 222. The BGA connectors 208 can be arranged such that the BGA connectors 208 are of equal or similar length connecting to the CA balls 114 in the first channel 110A and the second channel 110B.

In some embodiments, the interconnect electrical pad can be oriented identical to the electrical pad of the substrate layer. In some embodiments, the interconnect layer may not include an additional interconnect electrical pad, rather, the electrical pad can be connected without an intervening interconnect electrical pad to the CA balls through BGA connectors in the interconnect layer. In some embodiments, the interconnect electrical pads 220 and 224 can be configured as CA pads and can be connected to the CA balls 114 of the second channel 110B and the first channel 110A respectively. In some embodiments, interconnect electrical pad 222 can be configured as a DQ pad and be connected to the DQ balls 112 of the BGA 110.

FIG. 2C is a block diagram illustrating a side view of the substrate layer 212 including the electrical pads 120, 122, and 124, the interconnect layer 214 including the corresponding interconnect electrical pads 220, 222, and 224, the BGA 110, and BGA connectors 206, 208, and 210 according to one embodiment. Interconnect dual channel DDR package 200 can include, in some embodiments, a layer of memory cells for storing bits of data. In some embodiments, the memory cells of layer 216 can be physically and/or electrically separated into a first and second channel associated with the first channel 110A and the second channel 110B of the BGA 110. The memory cells of layer 216 can be accessed by the electrical pads 120, 122, and 124 of the substrate layer 212. The electrical pads 120, 122, and 124 are shown here within the circuit stripe 126 of the BGA 110 running in the-X direction such that the electrical pads 120, 122, and 124 are shown as one block, but are in a row running in the-X direction. In some embodiments, the electrical pads disposed within the substrate layer 212 and are in electrical contact with the memory cells 216 in the-Z direction and the interconnect electrical pads 220, 222, and 224 of the interconnect layer 214 in the Z direction.

In some embodiments, the electrical connections 202 and 204 between the electrical pads 220, 222, and 224 and the interconnect electrical pads 220, 222, and 224 do not cross and are disposed within the substrate layer 212. Electrical connections 202 and 204 are shown as dotted lines to indicate connections without indicated depth in the z direction. In some embodiments, an additional electrical connection can be disposed within the substrate layer 212 connecting the electrical pad 122 to the interconnect electrical pad 222. In some embodiments, a second interconnect layer can be disposed between the substrate layer 212 and the interconnect layer 214 in which the electrical connections between the electrical pads 120, 122, and 124 and the interconnect electrical pads 220, 222, and 224 are disposed. In some embodiments, the second interconnect layer can be a package substrate.

The interconnect layer 214 is disposed on the substrate layer 212 in the Z direction. In one embodiment, the interconnect layer includes the interconnect electrical pads 220, 222, and 224. In some embodiments, the interconnect layer can include additional or fewer interconnect electrical pads. In some embodiments, the interconnect electrical pads 220, 222, and 224 can be configured as DQ pads and CA pads.

In some embodiments, the interconnect layer 214 can include the BGA connectors 206, 208, and 210 as shown in FIG. 2B. In some embodiments, the BGA connectors 206, 208, and 210 can extend from the interconnect electrical pads 220, 222, and 224 in the X and-X directions of FIG. 2C. In some embodiments, the BGA connectors 206, 208, and 210 can extend from the interconnect electrical pads 220, 222, and 224 in a second interconnect layer disposed on the interconnect layer 214 in the Z direction. The BGA connectors 206, 208, and 210 can connect to the BGA 110 at the first channel 110A and/or the second channel 110B.

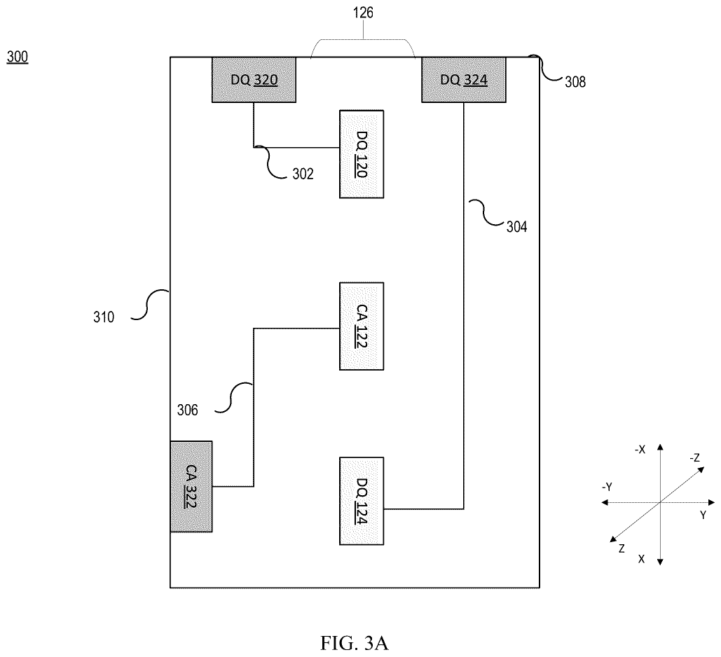

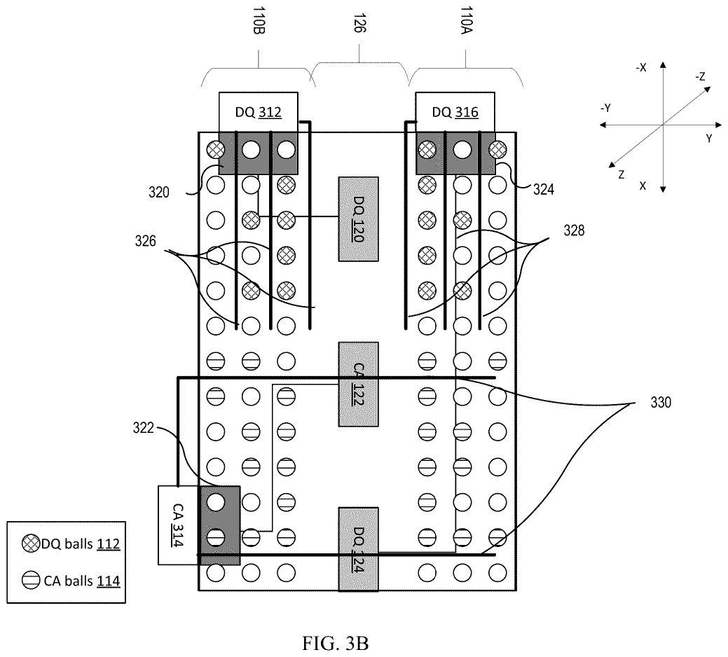

FIG. 3A is a block diagram illustrating a top view of vertical edge pad interconnect dual channel DDR package 300 with the electrical pads 120, 122, and 124 of FIG. 1 within the circuit stripe 126 and corresponding interconnect electrical pads 320, 322, and 324 deposited along multiple sides 308 and 310 of the vertical edge pad interconnect dual channel DDR package 300 according to electrical pad type and connected to the electrical pads 120, 122, and 124 according to one embodiment. In some embodiments, it is beneficial for electrical pads to be disposed on a side of a DDR package. Side disposed electrical pads can provide for stacked wire bonded packages which can allow for a reduction in package size, improved signal transmission between packages, and cost reduction. For example, arranging the electrical pads along a side may preserve or improve signal integrity by reducing the length of the electrical connections as discussed above. Additionally, edge placement of electrical pads may allow for better thermal management by allowing increased dissipation of heat provided by airflow at the edge. Space can be more efficiently utilized for a printed circuit board with a DDR package utilizing edge placement of electrical pads by allowing easier connection and/or more configurable connections.

FIG. 3A shows an embodiment of a substrate layer including electrical pads 120, 122, and 124 and an interconnect layer including interconnect electrical pads 320, 322, and 324 and disposed on the substrate layer in the Z direction a vertical edge pad interconnect dual channel DDR package 300. The interconnect layer can include one or more interconnect electrical pads such as interconnect DQ pad 320, interconnect CA pad 322, and interconnect DQ pad 324. The interconnect DQ pads 320 and 324 can each indicate a block of DQ pads on the interconnect layer, such that each interconnect DQ pad 320, 324 comprises one or more electrical pads configured for DQ signals. The interconnect CA pad 322 can indicate a block of CA pads on the interconnect layer, such that the interconnect CA pad 322 comprises one or more electrical pads configured for CA signals. Further, the interconnect layer can include electrical connections 302, 304, and 306 between the electrical pads 120, 122, and 124 of the substrate layer and the interconnect electrical pads 320, 322, and 324. As shown in FIG. 3A, in one embodiment, the interconnect electrical pads 320, 322, and 324 of the interconnect layer can be oriented along one or more edges of the vertical edge pad interconnect dual channel DDR package 300. In one embodiment, the electrical pads 120 and 124 can be configured as DQ pads. The interconnect electrical pads 320 and 324 can be disposed on a first side 308 of the vertical edge pad interconnect dual channel DDR package 300. Electrical connections 302 and 304 can connect the interconnect electrical pads 320 and 324 to the electrical pads 120 and 124. Electrical connections 302 and 304 can be disposed in the substrate layer or in an independent layer disposed between the substrate layer and the interconnect layer. The electrical pad 122 can be configured as a CA pad. The interconnect electrical pad 322 can be disposed on a second side 310 of the vertical edge pad interconnect dual channel DDR package 300. Electrical connection 306 can connect the interconnect electrical pad 322 to the electrical pad 122. Electrical connection 306 can be disposed in the substrate layer or in an independent layer disposed between the substrate layer and the interconnect layer.

Electrical connections 302, 304, and 306 can be wires, electrical pathways in a substrate, or other methods of electrical transmission. In some embodiments, the interconnect layer may further include additional electrical components. In some embodiments, the interconnect layer may be configured as a redistribution layer. In some embodiments the redistribution layer may include metal layers, such as copper, disposed on a dielectric substrate to act as the electrical connections. In some embodiments, the redistribution layer may include insulating portions to prevent electrical interference between components. In some embodiments, the electrical pathways may be vias within a substrate of the redistribution layer, such that the vias are small channels of conductive material within the substrate that allow for electrical connection.

FIG. 3B is a block diagram illustrating a top view of the vertical edge pad interconnect dual channel DDR package 300 illustrating the electrical pads 120, 122, 124, corresponding interconnect electrical pads 320, 322, and 324, a BGA 110, and external electrical pads 312, 314, and 316 according to one embodiment. FIG. 3B illustrates an embodiment in which the BGA 110 is disposed on the interconnect layer in the Z direction. As shown, in an embodiment, electrical pad 120 is situated closer in the x direction to the associated DQ balls 112 of the BGA 110 than electrical pad 124. However, interconnect electrical pads 320 and 324 are equal distance in the x direction from the DQ balls 112 of the BGA 110. As explained above, additional balls of the BGA 110, such as power balls and ground balls can be interspersed between the DQ balls 112 and the CA balls 114 to electrically connect the dual-channel DDR package 300 to power and ground. Other balls of BGA 110 may include, for example, control balls such as reset, alert, and the like to electrically connect the dual-channel DDR package 300 to one or more control sources to receive control signals.

Interconnect electrical pad 320, in some embodiments, can be connected to an external electrical pad 312. In some embodiments, interconnect electrical pad 320 and external electrical pad 312 can be configured as DQ pads and can be configured to connect with DQ balls 112 of a single channel 110B of the interconnect dual channel DDR package 300 using BGA connectors 326. Interconnect electrical pad 324, in some embodiments, can be connected to an external electrical pad 316. In some embodiments, interconnect electrical pad 324 and external electrical pad 316 can be configured as DQ pads and can be configured to connect with DQ balls 112 of a single channel 110A of the interconnect dual channel DDR package 300 using BGA connectors 328. BGA connectors 326 and 328, because of the proximity of interconnect electrical pads 320 and 324 and external electrical pads 312 and 316 to the DQ balls 112, can be of equal or similar length.

Interconnect electrical pad 322 can, in some embodiments, be connected to an external electrical pad 314. In some embodiments, interconnect electrical pad 322 and external electrical pad 314 can be configured as CA pads and can be configured to connect with CA balls 114 of the first channel 110A and the second channel 110B of the interconnect dual channel DDR package 300 using BGA connectors 330.

In some embodiments, the external electrical pads 312, 314, and 316 can be part of the interconnect dual channel DDR package 300 or can be connected to the interconnect dual channel DDR package 300 and can be disposed on the printed circuit board to which the interconnect dual channel DDR package 300 is attached.

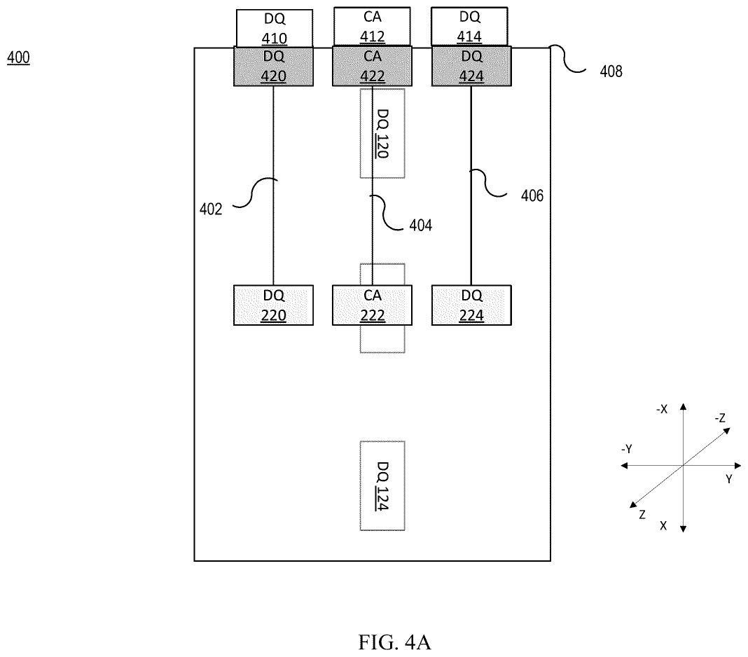

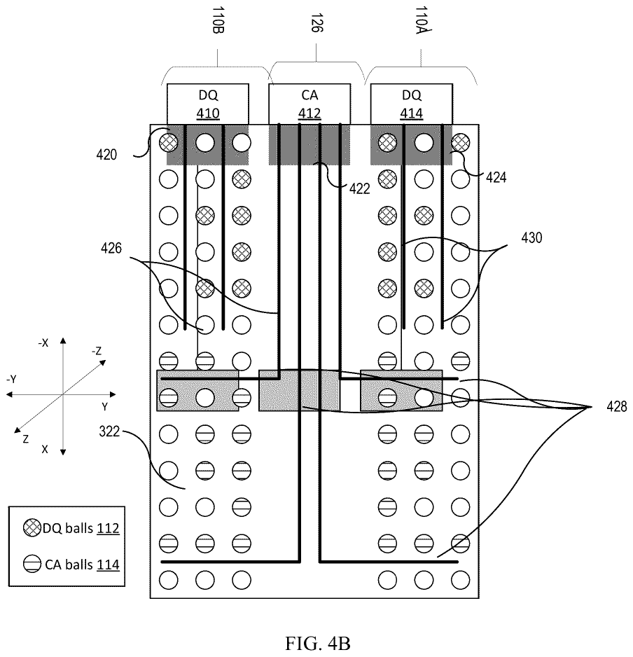

FIG. 4A is a block diagram illustrating a top view of the vertical pad interconnect dual channel DDR package of FIG. 2A including the interconnect electrical pads 220, 222, and 224, edge electrical pads 420, 422, and 424 deposited on a side of the DDR package 400 and connected to the interconnect electrical pads 220, 222, and 224, and external electrical pads 410, 412, and 414 according to one embodiment. The interconnect layer can include one or more interconnect electrical pads such as interconnect DQ pad 220, interconnect CA pad 222, and interconnect DQ pad 224. Further, the interconnect layer can include electrical connections between the electrical pads 120, 122, and 124 of the substrate layer and the interconnect electrical pads 220, 222, and 224. As shown in FIG. 2A, in one embodiment, the interconnect electrical pads 220, 222, and 224 of the interconnect layer can be oriented orthogonal to the circuit stripe 126 and the electrical pads 120, 122, and 124. The edge DQ pads 420 and 424 can each indicate a block of DQ pads on the side of the DDR package 400, such that each edge DQ pad 420, 424 comprises one or more electrical pads configured for DQ signals. The edge CA pad 422 can indicate a block of CA pads on the edge, such that the edge CA pad 422 comprises one or more electrical pads configured for CA signals.

In one embodiment, a second interconnect layer can be disposed on the interconnect layer including the interconnect electrical pads 220, 222, and 224. Interconnect electrical pads 220, 222, and 224 can be disposed on the substrate layer of FIG. 2A to orient the interconnect electrical pads orthogonally to the electrical pads. The second interconnect layer can include edge electrical pads 420, 422, and 424. By adding the interconnect layer between the substrate layer and the second interconnect layer, the electrical connections 402, 404, and 406 can orient the edge electrical pads 420, 422, and 424 on the internal side of the edge 408 of the DDR package 400, without the electrical connections 402, 404, and 406 crossing. Without the interconnect layer, electrical connection from electrical pad 122 to the edge pad 422 could contact electrical pad 120 or contact an electrical connection connecting electrical pad 420.

Edge electrical pads 420, 422, and 424, in some embodiments, may be configured to be in electrical connection with external electrical pads 410, 412, and 414. Where the edge electrical pads 420, 422, and 424 can be at an edge 408 of the DDR package 400, and are disposed internal to the DDR package 400, the external electrical pads 410, 412, and 414, can be at the edge 408 of the DDR package 400 and can be disposed external to the DDR package 400. The external electrical pads 410, 412, and 414 can be attached to the DDR package 400 or can be physically or electrically connected to the DDR package 400. In some embodiments, the external electrical pads 410, 412, and 414 are connected electrically and/or physically to the edge electrical pads 420, 422, and 424.

Electrical connections 402, 404, and 406 can be wires, electrical pathways in a substrate, or other methods of electrical transmission. In some embodiments, the interconnect layer or second interconnect layer may further include additional electrical components. In some embodiments, the interconnect layer and/or the second interconnect layer may be configured as a redistribution layer. In some embodiments the redistribution layer may include metal layers, such as copper, disposed on a dielectric substrate to act as the electrical connections. In some embodiments, the redistribution layer may include insulating portions to prevent electrical interference between components. In some embodiments, the electrical pathways may be vias within a substrate of the redistribution layer, such that the vias are small channels of conductive material within the substrate that allow for electrical connection.

FIG. 4B is a block diagram illustrating a top view of the vertical pad interconnect dual channel DDR package of FIG. 2B including the interconnect electrical pads 220, 222, and 224, edge electrical pads 420, 422, and 424 deposited on a side 408 of the DDR package 400 and connected to the interconnect electrical pads 220, 222, and 224, external electrical pads 410, 412, and 441, a BGA 110, and BGA connectors according to the embodiment. FIG. 4B illustrates an embodiment in which the BGA 110 is disposed on the second interconnect layer in the z direction, the second interconnect layer disposed on the interconnect layer the Z direction. As shown, in an embodiment electrical pad 120 is situated closer in the x direction to the associated DQ balls 112 of the BGA 110 than electrical pad 124. However, interconnect electrical pads 220 and 224 as well as edge electrical pads 420 and 424 and external electrical pads 410 and 414 are equal distance in the x direction from the DQ balls 112 of the BGA 110. Additional balls of BGA 110, such as power balls and ground balls can be interspersed between the DQ balls 112 and the CA balls 114 to electrically connect the dual-channel DDR package 400 to power and ground. Other balls of BGA 110 may include, for example, control balls such as reset, alert, and the like to electrically connect the dual-channel DDR package 100 to one or more control sources to receive control signals.

As stated above, in some embodiments it may be beneficial to arrange the electrical pads on an edge of a DDR package and/or connect to external electrical pads. Edge electrical pad 420, in some embodiments, can be a DQ pad configured to connect with an external electrical pad 410 configured as a DQ pad. The external electrical pad 410 can connect with DQ balls 112 of a single channel 110B of the interconnect dual channel DDR package 400 using BGA connectors 426. Edge electrical pad 424, in some embodiments, can be a DQ pad configured to connect with an external electrical pad 414 configured as a DQ pad. The external electrical pad 414 can connect with DQ balls 112 of a single channel 110A of the interconnect dual channel DDR package 400 using BGA connectors 430. BGA connectors 426 and 430, because of the proximity of edge electrical pads 410 and 414 to the DQ balls 112, can be of equal or similar length.

Edge electrical pad 422 can, in some embodiments, be disposed on the edge 408 of the DDR package 400 between edge electrical pad 420 and edge electrical pad 424. The location of the edge electrical pad 422 can allow for connection with an external electrical pad 412. External electrical pad 412 can be oriented such that all BGA connectors 408 from the external electrical pad 412 to the CA balls 114 of the BGA 110 connect to the external electrical pad 412 at a same side of the external electrical pad 412. The BGA connectors 408 can be arranged such that the BGA connectors 408 are equal or similar length connecting to the CA balls 114 in the first channel 110A and the second channel 110B.

In some embodiments, the interconnect electrical pads and/or the edge electrical pads can be oriented on one or more edges of the DDR package according to printed circuit board design such that electrical connections between the electrical pads, interconnect electrical pads, and/or edge electrical pads do not cross within the DDR package. In some embodiments, additional or fewer electrical pads and associated interconnect electrical pads and/or edge electrical pads may be used. In some embodiments, electrical pads, interconnect electrical pads, and/or edge electrical pads can be configured as DQ or CA pads. In some embodiments, three or more channels may be used with corresponding DQ or CA pads.

In the above description, numerous details are set forth. It will be apparent, however, to one of ordinary skill in the art having the benefit of this disclosure, that embodiments of the present disclosure may be practiced without these specific details. In some instances, well-known structures and devices are shown in block diagram form, rather than in detail, in order to avoid obscuring the description.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this disclosure, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this disclosure and the appended claims should generally be construed to mean “one or more” unless specified otherwise or clear from context to be directed to a singular form. Moreover, use of the term “an embodiment” or “one embodiment” or “an implementation” or “one implementation” throughout is not intended to mean the same embodiment or implementation unless described as such.

The above description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth above are merely exemplary. Particular implementations may vary from these exemplary details and still be contemplated to be within the scope of the present disclosure.

The description above includes specific terminology and drawing symbols to provide a thorough understanding of the present disclosure. In some instances, the terminology and symbols may imply specific details that are not required to practice the disclosure. For example, any of the specific numbers of bits, signal path widths, signaling or operating frequencies, component circuits or devices and the like may be different from those described above in alternative embodiments. Also, the interconnection between circuit elements or circuit blocks shown or described as multi-conductor signal links may alternatively be single-conductor signal links, and single conductor signal links may alternatively be multiconductor signal links. Signals and signaling paths shown or described as being single-ended may also be differential, and vice-versa. Similarly, signals described or depicted as having active-high or active-low logic levels may have opposite logic levels in alternative embodiments. Component circuitry within integrated circuit devices may be implemented using metal oxide semiconductor (MOS) technology, bipolar technology, or any other technology in which logical and analog circuits may be implemented. With respect to terminology, a signal is said to be “asserted” when the signal is driven to a low or high logic state (or charged to a high logic state or discharged to a low logic state) to indicate a particular condition. Conversely, a signal is said to be “de-asserted” to indicate that the signal is driven (or charged or discharged) to a state other than the asserted state (including a high or low logic state, or the floating state that may occur when the signal driving circuit is transitioned to a high impedance condition, such as an open drain or open collector condition). A signal driving circuit is said to “output” a signal to a signal receiving circuit when the signal driving circuit asserts (or de-asserts, if explicitly stated or indicated by context) the signal on a signal line coupled between the signal driving and signal receiving circuits. A signal line is said to be “activated” when a signal is asserted on the signal line, and “deactivated” when the signal is de-asserted. Additionally, the prefix symbol “/” attached to signal names indicates that the signal is an active low signal (i.e., the asserted state is a logic low state). A line over a signal name (e.g., ‘<̅s̅i̅g̅n̅a̅l̅ n̅a̅m̅e̅>̅’) is also used to indicate an active low signal. The term “coupled” is used herein to express a direct connection as well as a connection through one or more intervening circuits or structures. Integrated circuit device “programming” may include, for example and without limitation, loading a control value into a register or other storage circuit within the device in response to a host instruction and thus controlling an operational aspect of the device, establishing a device configuration or controlling an operational aspect of the device through a one-time programming operation (e.g., blowing fuses within a configuration circuit during device production), and/or connecting one or more selected pins or other contact structures of the device to reference voltage lines (also referred to as strapping) to establish a particular device configuration or operation aspect of the device. The term “exemplary” is used to express an example, not a preference or requirement. While the disclosure has been described with reference to specific embodiments thereof, it will be evident that various modifications and changes may be made thereto without departing from the broader spirit and scope of the disclosure. For example, features or aspects of any of the embodiments may be applied, at least where practicable, in combination with any other of the embodiments or in place of counterpart features or aspects thereof. Accordingly, the specification and drawings are to be regarded in an illustrative rather than a restrictive sense.

It is to be understood that the above description is intended to be illustrative and not restrictive. Many other embodiments will be apparent to those of skill in the art upon reading and understanding the above description. The scope of the disclosure should, therefore, be determined with reference to the appended claims, along with the full scope of equivalents to which such claims are entitled.

While the invention has been described with reference to specific embodiments thereof, it will be evident that various modifications and changes may be made thereto without departing from the broader spirit and scope of the invention. For example, features or aspects of any of the embodiments may be applied, at least where practicable, in combination with any other of the embodiments or in place of counterpart features or aspects thereof. Accordingly, the specification and drawings are to be regarded in an illustrative rather than a restrictive sense.

1. A dynamic random-access memory (DRAM) device, the DRAM device comprising:
a substrate layer comprising:
a circuit stripe;
a command address (CA) pad disposed within the circuit stripe; and
a first data queue (DQ) pad and a second DQ pad disposed within the circuit stripe, wherein the first DQ pad and the second DQ pad are separated by the CA pad;
a ball grid array layer comprising:
a DQ ball grid array configured to accept DQ connections; and
a CA ball grid array configured to accept CA connections,
wherein the DQ ball grid array and the CA ball grid array comprise a plurality of solder bumps; and
a first interconnect layer between the substrate layer and the ball grid array layer, wherein the first interconnect layer comprises:
an interconnect CA pad, wherein the interconnect CA pad is configured to connect to the CA ball grid array and is electrically connected to the CA pad via a CA wire; and
a first interconnect DQ pad and a second interconnect DQ pad, wherein the first interconnect DQ pad and the second interconnect DQ pad are configured to connect to the DQ ball grid array and are electrically connected to the first DQ pad and the second DQ respectively using a first DQ wire and a second DQ wire,
wherein the CA wire, the first DQ wire, and the second DQ wire do not intersect within the first interconnect layer.

2. The DRAM device of claim 1, further comprising a second interconnect layer between the first interconnect layer and the grid ball array layer, wherein the second interconnect layer comprises:
one or more connection lines from the first interconnect DQ pad to the DQ ball grid array;
one or more connection lines from the second interconnect DQ pad to the DQ ball grid array; and
one or more connection lines from the interconnect CA pad to the CA ball grid array.

3. The DRAM device of claim 2, wherein the first interconnect layer is a redistribution layer and the second interconnect layer is a package substrate.

4. The DRAM device of claim 1, wherein the first interconnect DQ pad, the second interconnect DQ pad, and the interconnect CA pad are within an interconnect stripe on the interconnect layer, and wherein the interconnect CA pad is deposited between the first interconnect DQ pad and the second interconnect DQ pad, and wherein the interconnect stripe is orthogonal to the circuit stripe.

5. The DRAM device of claim 1, wherein the first interconnect DQ pad, the second interconnect DQ pad, and the interconnect CA pad are deposited at an edge of the interconnect layer.

6. The DRAM device of claim 1, further comprising a plurality of memory cells of the substrate layer, wherein the plurality of memory cells are arranged in a first channel corresponding to the first DQ pad and a second channel corresponding to the second DQ pad.

7. The DRAM device of claim 1, wherein ball grid array further comprises:
a first half of the ball grid array, wherein the first half includes a first DQ half of the DQ ball grid array and a first CA half of the CA ball grid array; and
a second half of the ball grid array, wherein the second half includes a second DQ half of the DQ ball grid array and a second CA half of the CA ball grid array, wherein the circuit stripe is centered between the first half of the ball grid array and the second half of the ball grid array.

8. A dynamic random-access memory (DRAM) device, the DRAM device comprising:
a substrate layer comprising:
a circuit stripe;
a first component disposed within the circuit stripe; and
a second component and a third component disposed within the circuit stripe, wherein the second component and the third component are separated by the first component;
a ball grid array layer; and
a first interconnect layer between the substrate layer and the ball grid array layer, wherein the first interconnect layer comprises:
a first interconnect component, wherein the first interconnect component is configured to connect to the ball grid array layer and is electrically connected to the first component via a first wire; and
a second interconnect component and a third interconnect component, wherein the second interconnect component and the third interconnect component are configured to connect to the ball grid array layer and are electrically connected to the second component and the third component respectively using a second wire and a third wire,
wherein the first wire, the second wire, and the third wire do not cross within the first interconnect layer.

9. The DRAM device of claim 8, further comprising a second interconnect layer between the first interconnect layer and the grid ball array layer, wherein the second interconnect layer comprises:
one or more connection lines from the first interconnect component to the ball grid array layer;
one or more connection lines from the second interconnect component to the ball grid array layer; and
one or more connection lines from the third interconnect component to the ball grid array layer.

10. The DRAM device of claim 9, wherein the second interconnect layer is a package substrate.

11. The DRAM device of claim 8, wherein the first interconnect layer is a redistribution layer.

12. The DRAM device of claim 8, wherein the first interconnect component, the second interconnect component, and the third interconnect component are within an interconnect stripe on the interconnect layer, and wherein the first interconnect component is a first type and the second interconnect component and third interconnect component are a second type, the first interconnect component deposited between the second interconnect component and the third interconnect component and wherein the interconnect stripe is orthogonal to the circuit stripe.

13. The DRAM device of claim 8, wherein the first interconnect component, the second interconnect component, and the third interconnect component are deposited at an edge of the interconnect layer.

14. The DRAM device of claim 13, further comprising a first external interconnect component, a second external interconnect component, and a third external interconnect component deposited on an edge of the interconnect layer, external to the interconnect layer, wherein the first interconnect component, the second interconnect component, and the third interconnect component are electrically connected to the first external interconnect component, second external interconnect component, and the third external interconnect component respectively.

15. The DRAM device of claim 8, further comprising a plurality of memory cells of the substrate layer, wherein plurality of memory cells are arranged in a first channel corresponding to the second interconnect component and a second channel corresponding to the third interconnect component.

16. The DRAM device of claim 8, wherein ball grid array further comprises:
a first half of the ball grid array, wherein the first half includes a first DQ half of a DQ ball grid array and a first CA half of a CA ball grid array; ands
a second half of the ball grid array, wherein the second half includes a second DQ half of the DQ ball grid array and a second CA half of the CA ball grid array, wherein the circuit stripe is centered between the first half of the ball grid array and the second half of the ball grid array.

17. An integrated circuit comprising:
a first layer comprising:
a first component; and
a second component;
a ball grid array layer; and
a first interconnect layer between the first layer and the ball grid array layer, wherein the first interconnect layer comprises:
a first interconnect component, wherein the first interconnect component is configured to connect to the ball grid array layer and is electrically connected to the first component via a first wire; and
a second interconnect component, wherein the second interconnect component is configured to connect to the ball grid array layer and is electrically connected to the second component using a second wire,
wherein the first wire and the second wire do not cross within the first interconnect layer.

18. The integrated circuit of claim 17, further comprising a second interconnect layer between the first interconnect layer and the grid ball array layer, wherein the second interconnect layer comprises:
one or more connection lines from the first interconnect pad to the ball grid array; and
one or more connection lines from the second interconnect pad to the ball grid array.

19. The integrated circuit of claim 18, wherein the first interconnect layer is a redistribution layer and the second interconnect layer is a package substrate.

20. The integrated circuit of claim 17, wherein the first interconnect pad and the second interconnect pad are deposited at an edge of the interconnect layer.
